(19) United States
(12) Patent Application Publication
(10) Pub. No.: US 2006/0194442 A1
(43) Pub. Date: Aug. 31, 2006

(54) Procede method for cleaning a semiconductor

(76) Inventors: Jean-Luc Baltzinger, Draveil (FR); Elisabeth Asselin, Pringy (FR); Olivier Renaud, Saint Germain-Les-Corbell (FR)

Correspondence Address: SOFER & HAROUN, LLP, Suite 910, 317 Madison Avenue, New York, NY, 10017, US

(21) Appl. No.: 11/314,743

(22) Filed: Dec. 21, 2005

(30) Foreign Application Priority Data
Dec. 31, 2004 (FR) 04 53283

(51) Int. Cl. H01L 21/302

(52) U.S. Cl. 438/745

(57) ABSTRACT

A method for removing contaminating particles from the substrate of a semiconductor, comprising a step for depositing a thin film in dielectric material on the substrate. The method is characterized in that the deposition step is immediately followed by a chemical etching step for removing the deposited thin film.

### RELATED APPLICATION

This application is related to and claims the benefit of priority from, French Patent Application No. 04 53283, field on Dec. 31, 2004, the entirety of which is incorporated herein by reference.

### FIELD OF THE INVENTION

The present invention relates to the field of cleaning operations during manufacturing of semiconductors.

### BACKGROUND OF THE INVENTION

The method for manufacturing semiconductors conventionally involves masking steps: a photoresist layer is deposited. The semiconductor is next placed under a mask and then irradiated. Other intermediate operations, for example removal of the irradiated resin, etching of the unprotected areas by the remaining resin, may occur before removing the remaining resin.

At a relatively not very advanced stage of the manufacturing method, trenches (Shallow Trench Isolation, or STI) allow the locations of the future transistors to be separated from each other. As described in U.S. Pat. No. 6,391,739, a dielectric material may be applied in a relatively large amount in order to fill theses trenches. A portion of the applied dielectric material is then removed during a polishing operation, i.e., a mechanical-chemical erosion with which a substantially planar surface may be obtained. The polishing may be performed by using an abrasive material mixed with a chemical additive.

Upon manufacturing semiconductors, impurities, for example particles, may be deposited on the surface of the semiconductor and thereby contaminate the semiconductor.

The traditional methods for cleaning contaminating particles, for example jet cleaning, or else surface oxidization followed by chemical etching, have relatively low effectiveness.

US Patent application US2004/0134515 describes a method for cleaning a semiconductor. The method comprises a step for depositing an organic film and a mechanical removal step involving a supercritical fluid. However, this method is relatively complex to apply.

### OBJECTS AND SUMMARY

The present invention allows relatively simple and relatively effective cleaning of contaminating particles.

The object of the present invention is a method for removing contaminating particles from the substrate of a semiconductor, comprising a step for depositing a thin film in dielectric material on the substrate. According to the invention, this deposition step is immediately followed by a chemical etching step in order to remove the deposited thin film.

The deposited thin film preferably has an elastic constant different from the elastic constant of the substrate of the semiconductor on which the film is deposited, so that possible contaminating particles are relatively dissociated from the substrate because of the deposition step. Thus, when, immediately after deposition, i.e., without any particular intermediate step, the thin film is chemically etched, possible contaminating particles are detached from the substrate relatively easily. The chemical etching step allows the thin deposited film to be removed and facilitates removal of the contaminating particles.

The thin film deposition step advantageously comprises a low pressure chemical vapor deposition step or even an ion spray deposition method, or more generally according to any method allowing a thin film to be deposited on a substrate. For example, the thin film may be formed by spraying and drying a solution on the substrate.

The deposited thin film typically has a thickness of about 12 nanometers. With such a thin film thickness, it is possible to facilitate the removal of contaminating particles having a diameter of the order of one tenth of a nanometer, of the nanometer, of tens of nanometers, or even of the millimeter. Of course, this feature is not limiting: the deposited thin film may have a smaller thickness, for example of the order of one nanometer, or even more, for example of the order of a millimetre.

The dielectric material of the thin film may comprise silicon nitride. The use of silicon nitride is particularly advantageous when the substrate comprises silicon and/or silicon oxide.

In this case, chemical etching may comprise a step of passing into a phosphoric acid bath. Indeed, with phosphoric acid, it is possible to etch silicon nitride and therefore to remove the deposited thin layer.

Alternatively, the dielectric material of the thin film may comprise silicon oxide. The use of silicon oxide is particularly advantageous when the substrate comprises silicon and/or silicon nitride.

In this case, chemical etching may comprise a step of passing into a hydrofluoric acid bath. Indeed, with hydrofluoric acid, it is possible to etch silicon oxide and therefore remove the deposited thin layer.

Chemical etching may also comprise a step of passing through another bath, and more generally the removal of the deposited thin film may be achieved in any way involving chemical etching, as for example by dry etching via a plasma method.

Further, the present invention is of course limited neither by the composition of the dielectric material of the deposited thin film, nor by the composition of the substrate.

### BRIEF DESCRIPTION OF THE DRAWINGS

The invention is described hereafter in more detail by means of the figures which only illustrate a preferred embodiment of the invention.

FIG. 1 is a schematic sectional view of an exemplary semiconductor contaminated by a particle.

FIG. 2 is a schematic sectional view of the same semiconductor after a deposition step according to an embodiment of the present invention.

FIG. 3 is a schematic sectional view of the same semiconductor after a method according to an embodiment of the present invention.

### DETAILED DESCRITPION

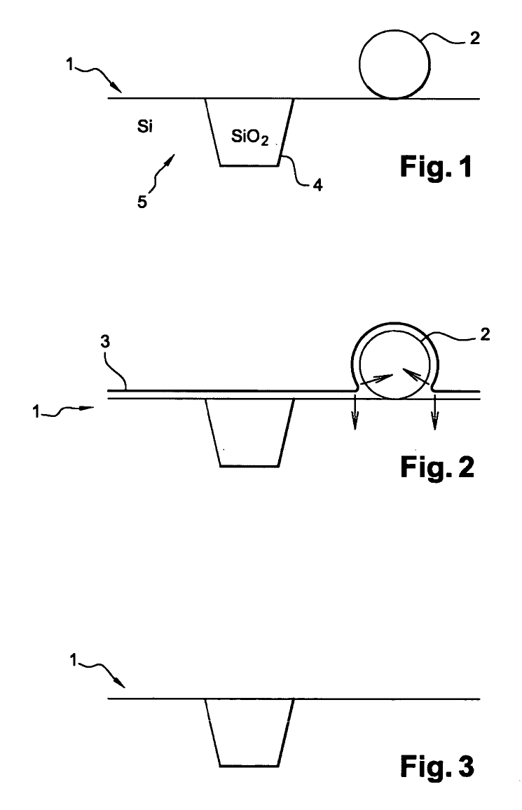

It will be noted that identical or similar components or portions have been designated by the same reference symbols in FIGS. 1, 2 and 3.

The illustrated exemplary semiconductor comprises a substrate 1 comprising a silicon oxide area 4 and a silicon area 5. A contaminating particle 2 is in contact with the substrate 1, so that if the additional layers are deposited, or if for example impurities are diffused into certain areas of the substrate 1, the semiconductor will not necessarily have the expected electrical behaviour.

According to the preferred embodiment of the present invention, a silicon nitride thin film 3 is deposited on the substrate. The deposition step occurs in the vapor phase at low pressure (Low Pressure Chemical Vapor Deposition or LPCVD).

The deposited thin film 3 has an elastic constant different from the elastic constant of the substrate 1 of the semiconductor, which generates stresses on film edges.

Thus, silicon has a Young modulus substantially around 169 GPa, or 130 GPa along the crystalline directions, whereas silicon nitride deposited in the vapor phase at low pressure has a Young modulus substantially around 275 GPa. The residual stress of a silicon nitride film deposited in the vapor phase at low pressure on a silicon substrate thus has a value substantially of 1.2 GPa.

In the case of a silicon nitride film deposited by plasma at 700° C., residual stress has substantially a value around 0.6 GPa. At 400° C., this value substantially passes around −0.7 GPa.

In particular, stresses, as illustrated in FIG. 2 by arrows, are generated around the contact surface between the contaminating particle 2 and the substrate 1, thus dissociating the contaminating particle 2 from the substrate 1.

After cooling, the thin film 3 is chemically etched by having the semiconductor pass into a phosphoric acid bath, thereby allowing the contaminating particle 2 to be removed with the thin film 3.

This succession of steps—deposition of a thin film followed by chemical etching for removing the deposited thin film—has the purpose of cleaning the substrate 1, i.e., removal of contaminating particles 2.

1. A method for removing contaminating particles from the substrate of a semiconductor, said method comprising the steps of:
depositing a thin film in dielectric material on the substrate; and
removing the deposited thin film immediately thereafter by a chemical etching step.

2. The method according to claim 1, wherein the step for depositing the thin film further comprises a low pressure chemical vapor deposition step.

3. The method according to claim 1, wherein the deposited thin film has a thickness of about 12 nanometers.

4. The method according to claim, wherein the dielectric material of the thin film further comprises silicon nitride.

5. The method according to claim 4, wherein the chemical etching further comprises a step of passing into a phosphoric acid bath.

6. The method according to claim 1, wherein the dielectric material of the thin film comprises silicon oxide.

7. The method according to claim 6, wherein the chemical etching comprises a step of passing into a hydrofluoric acid bath.
